(19) United States
(12) Patent Application Publication
(10) Pub. No.: US 2006/0027535 A1
(43) Pub. Date: Feb. 9, 2006

(54) Method and equipment for manufacturing liquid crystal display device

(75) Inventor: Hiroaki Furuya, Saitama-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/622,454

(22) Filed: Jul. 21, 2003

(30) Foreign Application Priority Data
Aug. 13, 2002 (JP) 2002-235530

(51) Int. Cl. C03C 15/00; H01L 21/306

(52) U.S. Cl. 216/97; 156/345.23

(57) ABSTRACT

First and second etching solutions 23 and 24 are used for etching treatments of glass substrates 11 and 12. The first etching solution 23 is faster in etching rate than the second one 24. The first etching solution first etches surface 11a of the glass substrate 11 and the surface 12a of the glass substrate 12. Even where there are the origins of pits 14 (concave defects) on the surfaces 11a and 12a, this etching treatment can remove them from the surfaces 11a and 12a because the etching runs faster than the occurrence of the pits. The second etching solution 24 which is slower in etching rare than the first one is then applied to etch the surfaces 11a and 12a. As a result, the etching treatments make the surfaces 11a and 12a as thin as desirable and sufficiently flat.

### FIELD OF THE INVENTION

This invention generally relates to a method and equipment for manufacturing a display device and, more particularly, to a method and equipment for manufacturing a display device to make a glass substrate thin and light.

### BACKGROUND OF THE INVENTION

Small size and light weight liquid crystal display (LCD) devices have been used for various apparatuses, such as mobile phones and handheld information processing terminals as display components but those apparatus demand much smaller and lighter LCD devices.

One of the factors in attempting to comply with such demand is to make a much thinner glass substrate for the LCD devices.

Where a thin glass substrate is used, however, from an initial stage of manufacturing LCD devices, it is so difficult to handle the glass substrates that manufacturing equipment faces many constraints. Further, since, with a thinner glass substrate, its warp or bend occurs more easily and its deformation increases with temperature changes, the productivity of LCD devices becomes lower. In addition, since a glass substrate with an arbitrary thickness results from such difficulty, it increases production cost to manufacture LCD devices with a desired thickness.

Manufacturing equipment has been recently developed, without substantial increases in manufacturing cost, to make a glass substrate thinner by applying mechanical or chemical etching treatment to surfaces of a pair of assembled glass substrates.

In such chemical etching treatment, however, if small defects or micro-cracks are made on the surface of a glass substrate in production processes, concave defects called “pits” occur on the surface of the glass substrate starting from the small defects or micro-cracks. The pits cause a low display quality of LCD devices.

### SUMMARY OF THE INVENTION

An object of the present invention is to provide a method and equipment for manufacturing LCD devices with substantial prevention of causing such pits on surfaces of glass substrates even if small defects or micro-cracks are made on the surfaces.

According to one aspect of the present invention, a method and equipment for manufacturing an LCD device includes the steps of preparing a plurality of etching solutions and carrying out a series of etching treatments for a glass substrate by using first one of the etching solutions with a faster etching rate and then that with a slower etching rate.

An etching treatment using an etching solution with a fast etching rate can remove small defects or micro-cracks from surfaces of a glass substrate if they exist on the surfaces because the etching rate is much faster than spreading rates of the small defects or micro-cracks. Subsequently, another etching treatment using an etching solution with a slow etching rate can lap and polish to give optically flat, damage free surfaces of the glass substrate. Further, such a series of etching treatments can also make the glass substrate optimal in thickness. Thus, the method and equipment for manufacturing an LCD device described above substantially prevent the surface of the glass substrate from causing concave flaws called pits stemming from the small defects or micro-cracks made on the surfaces prior to the etching treatments.

### BRIEF DESCRIPTION OF THE DRAWINGS

A more complete appreciation of the present invention and many of the attendant advantages thereof will be readily obtained as the same becomes better understood by reference to the following detailed descriptions when considered in connection with the accompanying drawings, wherein:

FIGS. 1A to 1F show schematically the steps of a method and equipment for manufacturing an LCD device in accordance with a first embodiment of the present invention; and

FIGS. 2A to 2C show changes of pits on a glass substrate in response to chemical etching treatments.

### DETAILED EXPLANATION OF THE PREFERRED EMBODIMENTS

An embodiment of the present invention will be explained below with reference to the drawings.

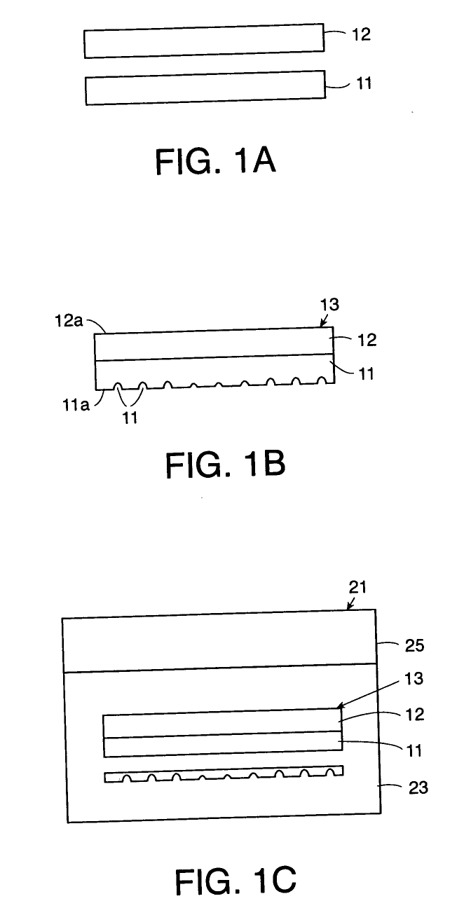

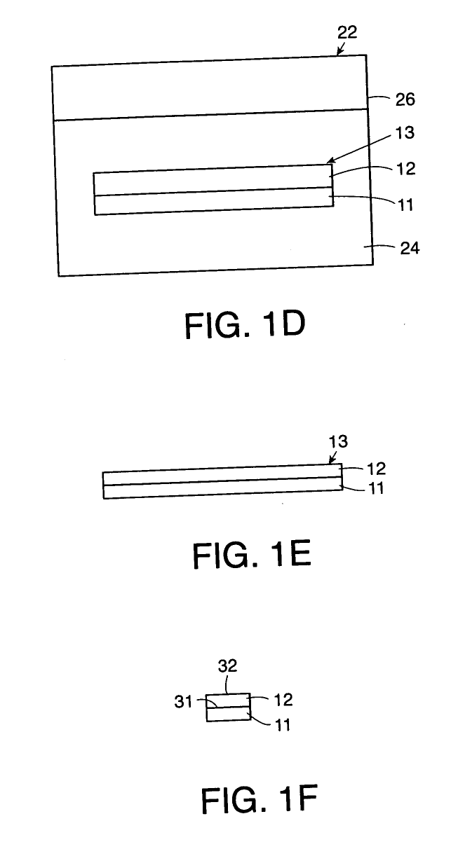

LCD cells are made between a pair of glass substrates 11 and 12 used for circuit array and counter substrates as shown in FIG. 1A, respectively. Their inner surfaces provided opposite to ach other have areas for forming LCD cell components and predetermined pixel electrode patterns.

The LCD cells made between the substrates each have inlets for injecting liquid crystal materials, cell s alants are coated to surround the pixel electrode patterns and enclosing sealants are coated on the inner peripheral edges of the glass substrates 11 and 12 except portions defining air discharging outlets. These cell and enclosing sealants made from epoxy resin system adhesives are coated by sealant dispensers, printing machines or the like. After the glass substrates 11 and 12 are put together by the sealants, the liquid crystal materials are injected into gaps between them and the air discharging outlets are closed with sealants, such as epoxy resin system adhesives. Thus, a plurality of the LCD cells are incorporated into an assembled member 13.

There are often the origins of pits 14, such as small defects, micro-cracks or the like made on the surface 11a of the glass substrate 11 and the surface 12a of the glass substrate 12 in the assembled member 13 in the production process. FIG. 1B shows schematically the origins of pits 14 on the surface of the glass substrate 11.

The surface 11a of the glass substrate 11 and the surface 12a of the glass substrate 12 in the assembled member 13 are then subjected to chemical etching treatments in etching process machines.

As such etching process machines, this embodiment includes first and second ones 21 and 22 shown in FIGS. 1C and 1D. The first and second etching process machines 21 and 22 have process containers 25 and 26, respectively, which contain first and second etching solutions 23 and 24, respectively. The etching rate of the first etching solution 23 is much faster than that of the second etching solution 24. The etching rate ratio of the former to the latter is set to be 100:1 or more. The first etching solution 23 is used at a normal temperature but the second etching solution is used at a slightly higher temperature than such normal one, thereby to adjust their etching rates and optimization.

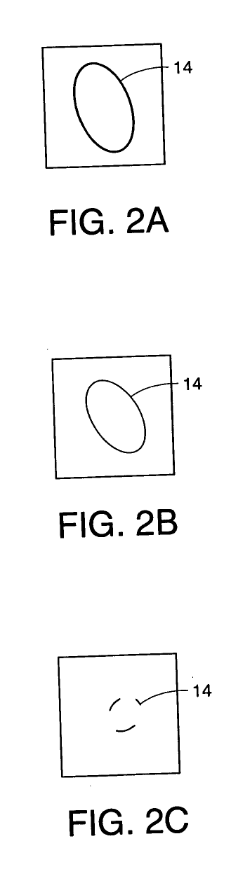

The etching treatment for the assembled member 13 is carried out in the following way. The assembled member 13 is first transferred by a carrier (not shown) to the first etching process machine 21 which, in turn, etches the surfaces 11a of the glass substrate 11 and the surface 12a of the glass substrate 12. Since the etching rate of the first etching solution 23 used in the first etching process machine 21 is fast enough to etch a relatively thick portion from the surfaces of the substrates in a short time. Thus, even though there are the origins of pits 14, e.g., small defects and micro-cracks on the surfaces 11a and 12a, the origins of pits 14 are removed from the surfaces because the etching runs faster than the pits spread from the origins. FIGS. 2A to 2C show schematically that the etching is removing the origins of pits 14 from the surface.

After the first etching in the first etching process machine 21 is completed, the carrier takes out the assembled member 13 from the first etching process machine 21 and transfers it to the second etching process machine 22, which further etches the surface 11a of the glass substrate 11 and the surface 12a of the glass substrate 12. Since the second etching solution 24 used in the second etching process machine 22 is relatively slow in etching rate, it takes time to gradually and uniformly etch the surfaces 11a and 12a until they become flat.

After the etching is completed in the second etching process machine 22, the carrier takes out the assembled member 13 from the second etching process machine 22 as shown in FIG. 1E. These etching treatments make the glass substrates 11 and 12 of the assembled member 13 as thin as desirable so that a light weight and thin LCD device can be provided.

As described above, the first and second etching solutions 23 and 24 with the different etching rates are used in such a way that the first etching solution 23 which is faster in etching rate than the second etching solution 24 and the second etching solution 24 are applied to etch the surface 11a of the glass substrate 11 and the surface 12a of the glass substrate 12 in that order. Thus, such etching treatments substantially suppress the occurrence of the pits even where there have been the origins of pits 14 on the surfaces 11a and 12a and improve a display quality of the LCD device.

Further, since the etching treatments are carried out after a pair of the glass substrates 11 and 12 are assembled, the glass substrates 11 and 12 can be handled while they remain thick so that the productivity is improved.

As also described above, the pixel electrode patterns are formed on each area provided for making LCD cell on a pair of glass substrates 11 and 12. The LCD cells each have inlets for injecting liquid crystal materials, cell sealants are coated to surround the pixel electrode patterns and enclosing sealants are coated on the inner peripheral edges of the glass substrates 11 and 12 except portions provided for air discharging outlets. After the glass substrates 11 and 12 are put together by the sealants, the liquid crystal materials are injected into gaps between them and the outlets are closed with sealants. A plurality of the LCD cells are finally incorporated into an assembled member 13. Since, therefore, the etching treatments can be carried out for such a plurality of the LCD cells as a whole, productivity is improved substantially.

In addition, since the etching rate ratio of the first etching solution to the second etching solution is set 100:1, the etching treatments can achieve both removal of the origins of pits 14 and flattening of the surfaces of the substrates.

Since the first and second etching solutions 23 and 24 are set a normal temperature and a higher one, respectively, the etching rate ratio can be adjusted and optimized between the first and second etching solutions 23 and 24.

Each LCD cell is cut out from the assembled member 13, the liquid crystal materials 31 are injected into the space between the glass substrates 11 and 12 through the inlets, which are then closed with sealants, and an LCD device 32 is produced as shown in FIG. 1F.

Instead of etching both the surface 11a of the glass substrate 11 and the surface 12a of the glass substrate 12, either one of them can be subjected to etching treatments to provide substantially the same results as the embodiment, i.e., a light weight and thin LCD device.

Further, three kinds of etching solutions with different etching rates or more can be used for multiple etching treatments. In this case, the etching rate ratio of the fastest etching rate solution to the slowest one can be much larger than the embodiment described above, thereby to remove the origins of pits 14 and to flatten the surfaces sufficiently.

According to the present invention, etching treatments for surfaces of glass substrates are first made with a faster etching rate solution and subsequently with a slower etching rate one to suppress the occurrence of concave defects called pits starting from small defects and micro-cracks on the surfaces existing prior to such etching treatments, thereby improving display quality of an LCD device.

What is claimed is:

1. A method of manufacturing a liquid crystal display device, comprising the steps of:
preparing glass substrates used for said liquid crystal display device;
preparing first and second etching solutions, said first etching solution being faster in etching rate than said second etching solution; and
etching surfaces of said glass substrates by using said first etching solution and then said second etching solution.

2. The method of manufacturing a liquid crystal display device according to claim 1, wherein said glass substrates include electrode patterns formed on said surfaces thereof and are put together, and said etching step is carried out for at least one surface of said glass substrates.

3. The method of manufacturing a liquid crystal display device according to claim 1, wherein a ratio of said etching rate of said first etching solution to that of said second etching solution is 100:1 or more.

4. Equipment for manufacturing a liquid crystal display device, comprising:
a carrier to take and transfer [this revision could be deleted if limiting] glass substrates used for said liquid crystal display device;
first and second etching solutions, said first etching solution being faster in etching rate than said second etching solution; and
an etching process machine to etch surfaces of said glass substrates by using said first etching solution and then said second etching solution.
